(19) United States
(12) Patent Application Publication
(10) Pub. No.: US 2007/0158684 A1
(43) Pub. Date: Jul. 12, 2007

(54) Compound semiconductor, method of producing the same, and compound semiconductor device

(75) Inventors: Kenji Kohiro, Tsukuba-Shi (JP); Kazumasa Ueda, Tsuchiura-Shi (JP); Toshimitsu Abe, Niihama-Shi (JP); Masahiko Hata, Tsuchiura-Shi (JP)

Correspondence Address: BIRCH STEWART KOLASCH & BIRCH, PO BOX 747, FALLS CHURCH, VA, 22040-0747, US

(73) Assignee: Sumitomo Chemical Company, Limited, Tokyo (JP)

(21) Appl. No.: 10/560,160

(22) PCT Filed: May 24, 2004
(86) PCT No.: PCT/JP04/07413

§ 371 Date: Jan. 29, 2007

(30) Foreign Application Priority Data
Jun. 13, 2003 (JP) 2003-169408
Apr. 23, 2004 (JP) 2004-127685

(51) Int. Cl. H01L 31/00

(52) U.S. Cl. 257/190

(57) ABSTRACT

An InGaP buffer layer (3) is formed on a semi-insulating GaAs substrate (1) to a thickness of not less than 5 nm and not greater than 500 nm and an InAlAs layer (4) and an InGaAs channel layer (5) are grown thereon to form a heterostructure. An In segregation effect occurs at the time of forming the InGaP buffer layer (3), so that the region of the InGaP buffer layer (3) near the layer above becomes excessive in In. As a result, the composition of the surface of the InGaP buffer layer (3) becomes very close to the composition of InP, thereby suppressing occurrence of misfit dislocations that can result in degradation of the surface condition. Further, the surface condition of the InAlAs layer (4) and InGaAs channel layer (5) formed thereon can be made good.

### TECHNICAL FIELD

The present invention relates to a compound semiconductor of low dislocation density, a method of producing the compound semiconductor, and a compound semiconductor utilizing the same.

### BACKGROUND ART

The compound semiconductor devices currently used in the power amplifiers, switches and the like of mobile telephones are chiefly ones formed in various heterostructures on a GaAs substrate by an epitaxial method or the like. For example, a high electron mobility transistor (HEMT) used as a microwave amplifying device or high-speed switching device in mobile telephones is a compound semiconductor device that has an n-type AlGaAs electron supply layer and an InGaAs channel layer formed on a GaAs substrate and that utilizes high mobility two-dimensional electron gas in the channel layer.

The increasing need for higher speed devices in recent years is forcing a switch from devices using a GaAs substrate to ones using an InP substrate. This is because use of an InP substrate results in a dramatic improvement in electron transport property owing to the fact that the In content of the InGaAs channel layer can be made greater than that in the case of using a GaAs substrate.

However, production of an InP substrate as a single crystal substrate is difficult because the stacking fault energy of InP is smaller than that of GaAs and, in addition, the price of InP is high, several times that of GaAs, owing to the high cost of In metal. Moreover, the InP substrate has a strength problem, namely it cracks easily, which makes use of InP substrates a cause of poor yield during epitaxial growth and the device fabrication process.

This strongly motivated attempts to fabricate a compound semiconductor by forming an InGaAs/InAlAs system epitaxial layer for an HEMT on a GaAs substrate in the same way as one would be formed on an InP substrate. However, the lattice constant of GaAs is 5.6533 Å while lattice constant of InP, and of In_{0.53}Ga_{0.47}As and In_{0.52}Al_{0.48}As that lattice-match InP, is 5.8688 Å, so that a mismatch in lattice constant of about 4% arises when the foregoing configuration is adopted. As a result, direct formation of these on a GaAs substrate introduces a large amount of misfit dislocations caused by lattice mismatching into the HEMT obtained in this way.

A known method for overcoming this problem is to provide a compositionally graded layer of InGaAs or InAlAs in a buffer layer on the GaAs substrate. In the past, there has most often been used the linearly graded buffer method of gradually changing the lattice constant of the compositionally graded layer in the thickness direction (see, for example, W. E. Hoke et al., J. Vac. Sci. Technol. B, 19 (2001) 1505) or the step-graded buffer method of changing the lattice constant of the compositionally graded layer stepwise in the thickness direction (see, for example, S. Goze et al., J. Cryst. Growth 201/202 (2001) 155). The former method minimizes occurrence of dislocations by gradually mitigating lattice strain in the buffer layer, and the latter method changes the composition stepwise to bend the dislocations at the interface and thereby prevent propagation of the dislocations to the layer above.

Both of these methods effectively reduce misfit dislocations, and prototype compound semiconductor devices using epitaxial substrates fabricated by these methods have actually been produced. However, neither of the methods has yet been practically applied in commercial production. The chief problem with the methods is that the buffer layer becomes very thick, reaching 0.5 μm or greater. When the linearly graded buffer method is used, for example, a buffer layer thickness of 1.5 μm is needed. This is because at a small film thickness the strain produced by the lattice mismatching concentrates in the thin buffer to make the dislocation density extremely high. On the other hand, when the step-graded buffer method is used, the buffer layer thickness can be made small because the dislocation direction changes at every buffer interface. As set out in the foregoing paper, even in this case the buffer layer thickness becomes as large as 0.6 μm. Thus it is difficult to achieve a film thickness of less than 0.5 μm in the case of a conventional buffer layer employing a compositionally graded layer.

Stacking of thick layers on a substrate increases cost owing to the larger amount of raw material needed and the longer growth time. The cost decrease realized by replacing an expensive InP substrate with a cheap GaAs substrate is therefore slight, so that an attempt to lower cost by this method is liable to fail.

Further, stacking of thick films degrades surface smoothness, so that an epitaxial substrate for fabricating an HEMT or other compound semiconductor device may adversely affect the mobility of the completed HEMT. In addition, a thick buffer layer experiences highly concentrated aggregation of dislocations. As a result, the electrical properties and reliability of a compound semiconductor device utilizing such a buffer layer tend to be degraded because leak current is liable to increase and reliability to decline in various aspects.

An object of the present invention is to provide a compound semiconductor capable of overcoming the foregoing problems of the prior art and a method of producing the compound semiconductor.

Another object of the present invention is to provide a compound semiconductor device excellent in electrical properties and reliability.

### DISCLOSURE OF THE INVENTION

Through assiduous research toward the achievement of the forgoing object, the inventors discovered that when an InGaP buffer layer or an InGaAsP buffer layer is formed on a GaAs substrate to a thickness of not less than 5 nm and not greater than 500 nm and a layer or the like of InP, InGaAs or InAlAs is thereafter overlaid on the buffer layer, a good surface condition with few surface defects is obtained. They accomplished the present invention based on this knowledge.

One characterizing feature of the present invention is that, in a compound semiconductor obtained by forming on a GaAs substrate a layer of InP crystal or a compound semiconductor crystal whose lattice constant is closer to that of InP than that of GaAs, the crystal is formed on the GaAs substrate via an InGaP buffer layer or an InGaAsP buffer layer and the thickness of the buffer layer is not less than 5 nm and not greater than 500 nm.

The compound semiconductor whose lattice constant is closer to that of InP than that of GaAs can be InGaAs or InAlAs crystal. The In content of at least the upper 5 nm of the InGaP buffer layer or InGaAsP buffer layer can be made higher than the content that lattice-matches with GaAs. The compound semiconductor can be used to produce an HEMT or other compound semiconductor device excellent in electrical properties and reliability.

Another characterizing feature of the present invention is that in a method of producing a compound semiconductor by growing on a GaAs substrate a layer of InP crystal or a compound semiconductor crystal whose lattice constant is closer to that of InP than that of GaAs, an InGaP buffer layer or InGaAsP buffer layer is grown on a GaAs substrate, and InP crystal or a compound semiconductor crystal whose lattice constant is closer to that of InP than that of GaAs is grown on the InGaP buffer layer or InGaAsP buffer layer.

### BRIEF DESCRIPTION OF THE DRAWINGS

FIG. 1 is layer structure diagram showing an embodiment of the compound semiconductor according the present invention.

FIG. 2 is a graph showing the results obtained by measuring the density distribution of Ga and In exhibiting In segregation in the InGaP layer of FIG. 1.

FIG. 3 is layer structure diagram showing another embodiment of the compound semiconductor according the present invention.

### BEST MODE OF CARRYING OUT THE INVENTION

In order to explain the present invention in greater detail, it will now be explained with reference to the attached drawings. Although the explanation will be made with respect to the case of an InGaP buffer layer, the invention is not limited to this embodiment and it is possible to treat InGaAsP, for example, in exactly the same way.

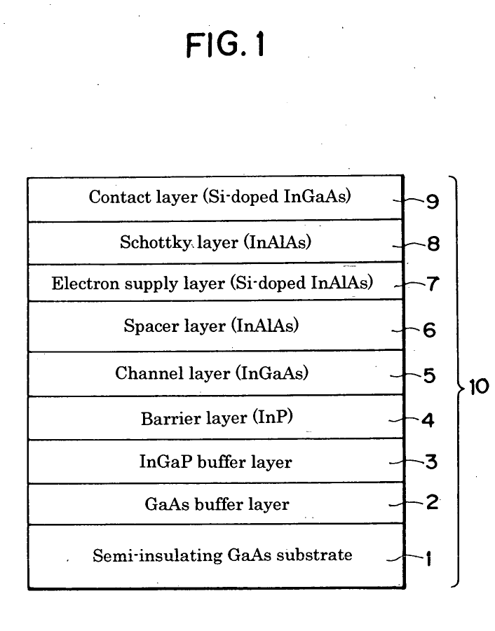

FIG. 1 is layer structure diagram showing an embodiment of the compound semiconductor according the present invention. A compound semiconductor epitaxial substrate 10 has a GaAs buffer layer 2 and an InGaP buffer layer 3 formed in this order on a GaAs substrate 1. Formation of the GaAs buffer layer 2 can be omitted.

In the present embodiment, the thickness of the InGaP buffer layer 3 is 30 nm. The In content thereof, defined as the ratio of the number of moles of In to the total number of moles of In and Ga, is higher than 0.48 within the range of about the upper 5 nm, i.e., within the range of about 5 nm from the boundary between this layer and a barrier layer 4 above, and is 0.48 outside this range. It suffices for the InGaP buffer layer 3 to have a thickness within the range of not less than 5 nm and not greater than 500 nm.

InGaP and GaAs lattice-match when the In content is 0.48. The value 0.48 can be calculated from the generally known III-V group four-element phase diagram (see, for example, Haruo Nagai, Sadao Adachi and Takashi Fukui, III-V Zoku Handotai Konsho (III-V Group Semiconductor Mixed Crystal), Corona, Ltd. (1988)). The In content of InGaAsP that lattice-matches GaAs can be similarly determined. The In content in this case depends on the As content. For example, if the As content is made 0.5, the In content becomes 0.24. For a different As content, the In content is also different.

Above the InGaP buffer layer 3 are formed in order a barrier layer 4 composed of InP, a channel layer 5 composed of InGaAs of an In content of 0.53, and a spacer layer 6 composed of InAlAs of an In content of 0.52. Above the spacer layer 6 are further formed in order an electron supply layer 7 composed of Si-doped InAlAs of an In content of 0.52, a Schottky layer 8 composed of InAlAs of an In content of 0.52, and a contact layer 9 composed of InGaAs of an In content of 0.53 and doped with Si.

The layers formed on the semi-insulating GaAs substrate 1 can, for example, be progressively grown by the metalorganic chemical vapor deposition method (hereinafter called the MOCVD method). In the case of forming the InGaP buffer layer 3, the InGaP buffer layer 3 is formed as if to achieve a uniform In content of 0.48. Actually, however, owing to the In segregation effect, the region of the InGaP buffer layer 3 near the barrier layer 4, namely the within the range of about the upper 5 nm of the InGaP buffer layer 3, comes to have an In content considerably greater than 0.48, so that In becomes excessive near the boundary with the barrier layer 4. On the other hand, Ga in the InGaP buffer layer 3 becomes deficient near the boundary with the barrier layer 4.

As a result, a layer having compound semiconductor crystal whose lattice constant is closer to that of InP than that of GaAs is formed above the region excessive in In of the uppermost surface of the InGaP buffer layer 3. This means that the result is the substantially the same as that of forming a layer or the like having compound semiconductor crystal whose lattice constant is closer to that of InP than that of GaAs on an InP layer. Therefore, the composition of the surface of the InGaP buffer layer 3 formed on the semi-insulating GaAs substrate 1 is very close to the composition of InP composition, so that occurrence of misfit dislocations that can result in degradation of the surface condition of the InGaP buffer layer 3 can be suppressed even though the lattice mismatching is very large.

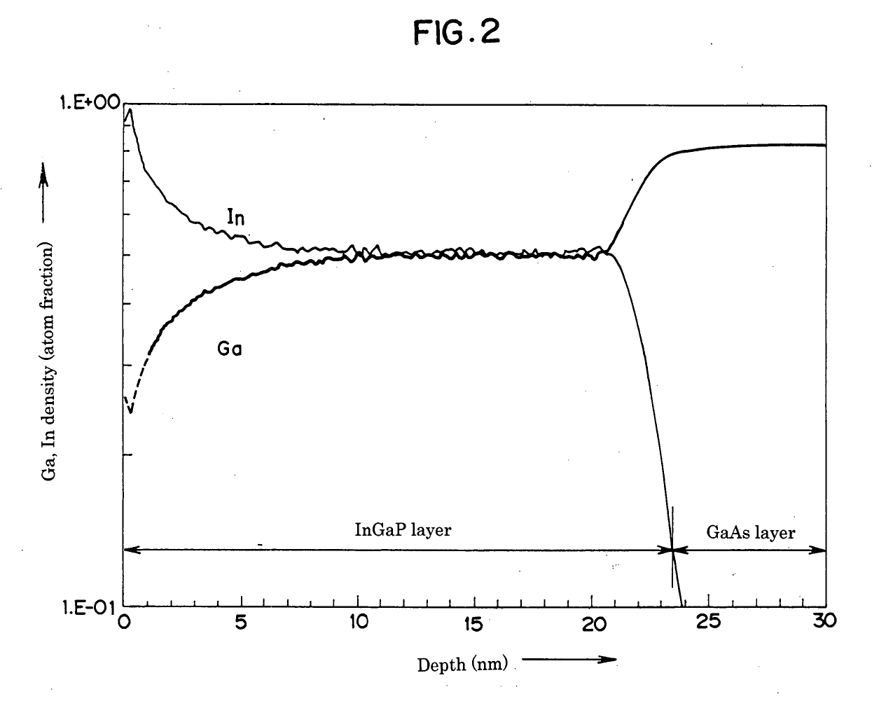

For confirmation, a specimen having an InGaP layer formed on a GaAs substrate was used to actually measure the Ga and In density distribution in the InGaP layer. FIG. 2 is a graph showing the measurement results. The graph of FIG. 2 shows the results obtained by forming on a GaAs substrate by the MOCVD method an InGaP layer of about 24 nm thickness as if to achieve an In content of 0.48 and measuring the density of In and Ga in the InGaP layer by SIMS analysis. The horizontal axis represents depth from the surface of the InGaP layer and the vertical axis represents In and Ga density.

As can be seen from FIG. 2, even though the InGaP layer was grown as if to achieve a uniform In content of 0.48, in actuality In of the uppermost surface became excessive. On the other hand, Ga was deficient at the uppermost surface. When the surface condition of the obtained specimen was observed, it was found to have a Haze value of several ppm. From this also it will be understood that the InGaP layer surface had a composition very close to InP, so that occurrence of misfit dislocations that can result in degradation of the surface condition of the InGaP layer can be suppressed even though the lattice mismatching is very large.

Although the thickness of the layer of the InGaP layer in which In is excessive depends on the growth temperature and the like, it can be seen from FIG. 2 to be around 5 nm or greater. It is thought that when the thickness of the InGaP layer is too small, the stress produced by the lattice misfits per unit thickness becomes too large, so that the effect of suppressing occurrence of misfit dislocations expected in the present invention declines.

Next, in order to study the growth conditions of the InGaP buffer layer, an InGaP layer and then an InP layer were formed on a GaAs substrate to thicknesses of 30 nm and 100 nm, respectively, by the MOCVD method to fabricate a compound semiconductor epitaxial substrate. Growth temperatures in the range of 400-700° C. were studied for each epitaxial film. Dependence of the surface condition of the obtained epitaxial substrate on growth temperature was observed and the Haze value was also measured. The results were as follows.

| Growth temp. (° C.) | Surface condition | Haze value (ppm) |
|---|---|---|
| 400-580 | Mirror finish | Several hundreds-1,000 |
| 580-600 | Mirror finish | 1,000-2,000 |
| 600-700 | Cloudy | Several thousands-several |
| | | tens of thousands |

The surface turned cloudy at a growth temperature of 600° C. or higher. At a temperature below 600° C., an excellent mirror finish was obtained on the surface, and of particular note is that the Haze value was under 2,000 ppm at a temperature below 580° C. Therefore, the InGaP buffer layer 3 is preferably grown under a growth temperature condition of not lower than 400° C. and not higher than 600° C., more preferably under a growth temperature condition of 400° C.-580° C.

Next, compound semiconductor epitaxial substrates were fabricated by fixing the MOCVD growth temperature at 550° C. and forming an InGaP buffer of one of various thicknesses in the range of 15 nm-300 nm and further forming an InP layer of 100 nm thereon. Dependence of the surface condition of the obtained epitaxial substrate on thickness of the InGaP buffer was observed and the Haze value was also measured. The results were as follows.

| InGaP layer | | |
|---|---|---|
| thickness (nm) | Surface condition | Haze value (ppm) |
| 15-100 | Mirror finish | Several hundreds-1,300 |
| 100-300 | Mirror finish | Several hundreds-2,000 |

As can be seen from these results, the Haze value tended to decrease with increasing thickness of the InGaP. However, the change in value by this decrease was very small. Further, as can be seen from FIG. 2, the composition of the InGaP layer started to be affected owing to In segregation at a distance of 5 nm-10 nm from the surface. From this it can be presumed that the minimum thickness capable of effectively confining dislocations is around 5 nm-10 nm. As the thickness of the InGaP layer increased from this minimum thickness, the surface condition of the InGaP layer progressively improved. However, when the thickness increased beyond around 100 nm, the degree of improvement became small. Judging from the foregoing facts, it is considered that when a layer high in In content is present in the InGaP layer, particularly near the upper most surface thereof, and in addition the InGaP layer is grown to a thickness of 5 nm or greater at below 600° C., misfit dislocations caused by lattice mismatching can be effectively confined.

The thickness of the InGaP buffer layer or InGaAsP buffer layer is ordinarily not less than 5 nm and not greater than 500 nm but is preferably not less than 5 nm and not greater than 300 nm, more preferably not less than 5 nm and not greater than 100 nm, and still more preferably not less than 10 nm and not greater than 50 nm.

Since the compound semiconductor epitaxial substrate 10 shown in FIG. 1 is configured in line with the foregoing thinking, it enables formation of a thin lattice mismatch system buffer layer of high quality.

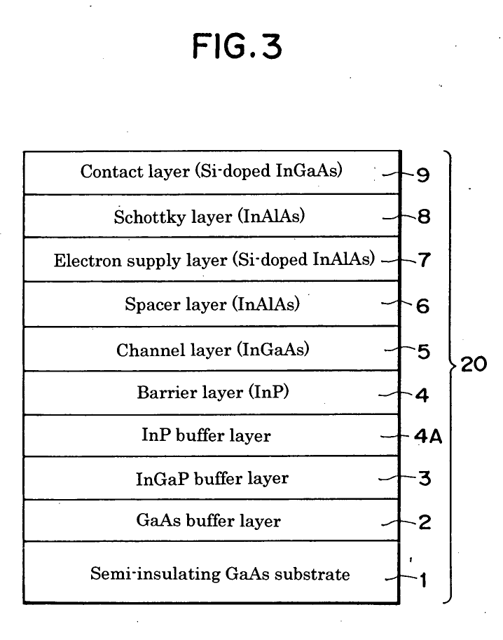

Another embodiment of the present invention will now be explained with reference to FIG. 3. The inventors pursued intense research for further enhancing the effect of the InGaP buffer layer in the configuration shown in FIG. 1. As a result, they discovered that by growing an InP buffer layer at a relatively low temperature following the InGaP buffer layer and further conducting annealing at a relatively high temperature, it is possible to lower the dislocation density still further and thus to manufacture a compound semiconductor device having improved device characteristics.

This thinking is applied the compound semiconductor 20 shown in FIG. 3, which differs from the compound semiconductor 10 of FIG. 1 only in the point that an InP buffer layer 4A is provided between the InGaP buffer layer 3 and the barrier layer 4 composed of InP. The parts in FIG. 3 corresponding to parts in FIG. 1 are therefore assigned the same symbols as in FIG. 1 and explanation thereof will be omitted.

The constitution of the buffer layers adopted in FIG. 3 will be explained. When a separate buffer layer is grown following the InGaP buffer layer in order to enhance the dislocation density lowering effect, it follows from consideration of thermal conductivity that the separate buffer layer has to be InP. This is because the thermal conductivity coefficients of InGaAs and InAlAs are small. InAlAs, InGaAs and other ternary system compound semiconductors are lower in thermal conductivity than InP, GaAs and other binary system compound semiconductors. Therefore, when such a compound semiconductor is used to manufacture a compound semiconductor device, the device obtained does not adequately dissipate heat during operation, so that the device temperature rises to degrade the device properties. The thermal conductivity of InGaAs, for example, is 0.05 W/cm·° C., while that of InP is 0.68 W/cm·° C. So the difference is about an order of ten.

Moreover, from the fact that the In density near the surface of the InGaP buffer layer 3 is high, making the composition of the InGaP buffer layer 3 close to that of InP, it follows that the formation of the InP buffer layer 4A immediately above the InGaP buffer layer forms an interface low in lattice constant difference (low in lattice mismatching). The growth temperature of the InP buffer layer 4A has a bearing on the smoothness and dislocation density near the surface of the InGaP buffer layer 3. The InGaP buffer layer 3 is thin, good in flatness and low in misfit dislocations and the like. However, by appropriately selecting the growth conditions of the InP buffer layer 4A formed in contact with the InGaP buffer layer 3, it is possible to make the flatness of the surface of the InP buffer layer 4A better than the flatness of the surface of the InGaP buffer layer 3. The inventors therefore carried out a further study regarding the growth temperature and thickness of the InP buffer layer 4A.

For conducting the study, an InGaP layer of 30 nm thickness was first grown on a GaAs substrate at 550° C. by the MOCVD method and an InP layer was grown on the InGaP layer to a thickness of 50 nm at a growth temperature in the range of 400° C.-600° C. In addition, an InP layer was grown to a thickness of 500 nm at a growth temperature of 550° C. to fabricate an epitaxial substrate. The surface state of the so-obtained epitaxial substrate was then evaluated. The results were as follows.

| Growth temp. (° C.) | Surface condition | Haze value (ppm) |
|---|---|---|
| When ≧400, ≦450 | Mirror finish | Several hundreds-1000 |
| When >450, ≦500 | Mirror finish | Several hundreds-2000 |
| When >500, ≦550 | Mirror finish | 1000-2000 |
| When >550, ≦600 | Cloudy | Several thousands-10,000 |

There was observed a tendency not to assume a good mirror finish when the growth temperature exceeded 550° C. At a growth temperature of 550° C. or lower, the surface had a good mirror finish and the Haze value was 2,000 ppm or lower. At a growth temperature below 400° C., PH₃ decomposition was insufficient and the InP layer growth rate was very slow. The InP layer growth temperature is therefore preferably not lower than 400° C. and not higher than 550° C., more preferably not lower than 400° C. and not higher than 500° C.

After growth of the InP buffer layer, the slight amount of remaining lattice strain can be totally relieved by annealing at a temperature not lower than 650° C. and not higher than 730° C., whereby misfit dislocations are also looped to prevent propagation to the layer above. The annealing operation is preferably conducted immediately after InP buffer growth.

Since the compound semiconductor epitaxial substrate 10 shown in FIG. 3 is constituted in line with the foregoing thinking, it becomes a compound semiconductor that affords a compound semiconductor device having excellent properties notwithstanding that the thickness of the buffer layers is small. When the buffer layer structure shown in FIG. 3 is adopted, it suffices for the total thickness of the InGaP buffer layer 3 and InP buffer layer 4A to be in the range of not less than 5 nm and not greater than 500 nm. Similarly, when an InGaAsP buffer layer is used instead of the InGaP buffer layer 3, it suffices for the total thickness of the InGaAsP buffer layer and InP buffer layer 4A to be in the range of not less than 5 nm and not greater than 500 nm.

The total of the InGaP buffer layer or InGaAsP buffer layer thickness and the InP buffer layer thickness should be not less than 5 nm and not greater than 500 nm and is preferably not less than 25 nm and not greater than 500 nm, more preferably not less than 25 nm and not greater than 200 nm, and still more preferably not less than 30 nm and not greater than 130 nm.

The thickness of the InP buffer layer is preferably not less than 20 nm and not greater than 200 nm, more preferably not less than 20 nm and not greater than 100 nm, and still more preferably not less than 20 nm and not greater than 80 nm.

An InP barrier layer is preferably formed on the InP buffer layer in order to prevent the slight amount of dislocations remaining in the InP buffer layer from propagating to the layer above. The growth temperature of the InP barrier layer can be the conventional InP growth temperature. In the MOCVD method, for instance, it is around 550° C.-700° C.

### WORKING EXAMPLES

Although the present invention will be more concretely explained with reference to working examples in the following, the present invention is not limited to these working examples. While these working examples are set out taking a high electron mobility transistor (HEMT) as an example, similar application to a heterobipolar transistor (HBT) or p-i-n photodiode is possible. The growth method used in the working examples is the metalorganic chemical vapor deposition (MOCVD) method, but it is also possible to use the molecular beam epitaxy (MBE) method or the like. Although an InGaP buffer layer is taken by way of example in the working examples, an InGaAsP buffer layer can be similarly used.

### Example 1

An HEMT epitaxial substrate having the compound semiconductor heterostructure of the layer structure shown in FIG. 1 was fabricated as follows using the MOCVD method. The semi-insulating GaAs substrate 1 was placed in a MOCVD film fabrication machine and elevated in temperature to conduct substrate surface treatment, whereafter the buffer layer 2 constituted as a GaAs layer was formed on the semi-insulating GaAs substrate using AsH₃ gas and metalorganic compound as feedstock. Next, the AsH₃ gas was switched to PH₃ gas to form the InGaP buffer layer 3 (In content, 0.48) to a thickness of 30 nm. The InGaP buffer layer growth temperature at this time was 550° C. The temperature was suitably adjusted and the feedstock progressively changed to form in order the InP layer 4 (In content, 0.52), InGaAs channel layer 5 (In content, 0.53), InAlAs spacer layer 6 (In content, 0.52), electron supply layer (Si planar doped layer) 7, InAlAs Schottky layer 8 (In content, 0.52), and Si-doped InGaAs contact layer 9 (In content, 0.53). The surface condition of the obtained epitaxial substrate was excellent; absolutely no cloudiness, crosshatching or the like was observed.

Next, the foregoing HEMT epitaxial substrate was evaluated by Hall measurement using the van der Pauw technique. The contact layer 9 of the epitaxial substrate was removed by etching and Hall measurement was performed at room temperature. The mobility of 9,100 cm²/V·s exhibited was a value comparable to that of an HEMT epitaxial substrate using an InP substrate.

### Example 2

An HEMT epitaxial substrate was fabricated under exactly the same conditions as in Example 1 except that the InGaP buffer growth temperature was 500° C. and the thickness thereof was 15 nm. The surface condition of the obtained epitaxial substrate was excellent; absolutely no cloudiness, crosshatching or the like was observed.

The contact layer 9 of the epitaxial substrate was removed by etching and Hall measurement was performed at room temperature. The mobility of 8,900 cm²/V·s exhibited was a value comparable to that of an HEMT epitaxial substrate using an InP substrate.

### Example 3

An HEMT epitaxial substrate having the compound semiconductor heterostructure of the layer structure shown in FIG. 3 was fabricated as follows using the MOCVD method. As in Example 1, the InGaP buffer layer 3 (In content, 0.48) was formed to a thickness of 30 nm. The InGaP buffer layer growth temperature at this time was 550° C. The temperature was then lowered to 435° C. and the InP buffer layer 4A was formed to a thickness of 50 nm. The temperature was next raised to the annealing temperature of 650° C. and annealing was preformed. After lowering the temperature to 640° C., the feedstock was progressively changed to form in order the InP layer 4, InGaAs channel layer 5 (In content, 0.53), InAlAs spacer layer 6 (In content, 0.52), Si planar doped layer 7, InAlAs Schottky layer 8 (In content, 0.52), and Si-doped InGaAs contact layer 9 (In content, 0.53). The surface condition of the obtained epitaxial substrate was excellent; no cloudiness, crosshatching or the like was observed.

Next, the contact layer 9 of the foregoing HEMT epitaxial substrate was etched and Hall measurement was performed at room temperature. The mobility of 9,100 cm²/V·s exhibited was a value substantially comparable to that of an HEMT epitaxial substrate manufactured using an InP substrate.

### Example 4

The Example 3 was repeated through the growth of the InP buffer layer 4A, whereafter the temperature was raised to the annealing temperature of 700° C. and annealing was preformed, and then growth of the layers after InP barrier layer 4 was carried out under exactly the same conditions as in Example 3 to fabricate an HEMT epitaxial substrate. The surface condition of the obtained epitaxial substrate was excellent; absolutely no cloudiness, crosshatching or the like was observed.

The contact layer 9 of the HEMT epitaxial substrate was etched and Hall measurement was performed at room temperature. The mobility was 9,600 cm²/V·s, which is a still better result than that in Examples 1 to 3.

### Example 5

The Example 3 was repeated through the growth of the InP buffer layer 4A, whereafter the temperature was raised to the annealing temperature of 700° C. and annealing was preformed, and then to the contrary the temperature was lowered to 480° C. Thereafter, raising and lowering of the temperature between 480° C. and 700° C. was carried out three times (increase to 700° C. a total of four times), and then with the temperature at 480° C., growth following the InP barrier layer 4 was conducted the same as in Example 3 to fabricate an HEMT epitaxial substrate. The surface condition of the obtained epitaxial substrate was excellent; absolutely no cloudiness, crosshatching or the like was observed.

The uppermost contact layer 9 of the HEMT epitaxial substrate was etched and Hall measurement was performed at room temperature. The mobility was 10,100 cm²/V·s, which is a still better result than that in Example 4.

1. A compound semiconductor obtained by forming on a GaAs substrate a layer of Inp crystal or a compound semiconductor crystal whose lattice constant is closer to that of InP than that of GaAs, which compound semiconductor is characterized in that:
the crystal is formed on the GaAs substrate via an InGaP buffer layer or an InGaAsP buffer layer; and
the thickness of the buffer layer is not less than 5 nm and not greater than 500 nm.

2. A compound semiconductor obtained by forming on a GaAs substrate a layer of InP crystal or a compound semiconductor crystal whose lattice constant is closer to that of InP than that of GaAs, which compound semiconductor is characterized in that:
an InGaP buffer layer or an InGaAsP buffer layer is formed on the GaAs substrate and an InP buffer layer is further formed on the InGaP buffer layer or InGaAsP buffer layer;
the crystal is formed via the two buffer layers;
and the total thickness of the two buffer layers is not less than 5 nm and not greater than 500 nm.

3. The compound semiconductor as claimed in claim 2, wherein the total thickness of the two buffer layers is not less than 25 nm and not greater than 500 nm.

4. The compound semiconductor as claimed in claim 2 or 3, wherein the thickness of the InP buffer layer is in the range of not less than 20 nm and not greater than 200 nm.

5. The compound semiconductor as claimed in claim 1, wherein the compound semiconductor crystal whose lattice constant is closer to that of InP than that of GaAs is InGaAs or InAlAs crystal.

6. The compound semiconductor as claimed in claim wherein the In content of at least the upper 5 nm of the InGaP buffer layer or InGaAsP buffer layer is higher than the content that lattice-matches with GaAs.

7. A compound semiconductor device comprising the compound semiconductor of claim 1.

8. A method of producing a compound semiconductor by growing on a GaAs substrate InP crystal or a compound semiconductor crystal whose lattice constant is closer to that of InP than that of GaAs, which method of producing a compound semiconductor is characterized in that:
an InGaP buffer layer or InGaAsP buffer layer is grown on a GaAs substrate; and
an InP crystal or a compound semiconductor crystal whose lattice constant is closer to that of InP than that of GaAs is grown on the InGaP buffer layer or InGaAsP buffer layer.

9. The method of producing a compound semiconductor as claimed in claim 8, wherein growth of the InGaP buffer layer or InGaAsP buffer layer is conducted at a temperature of not lower than 400° C. and not higher than 600° C. to a thickness of not less than 5 nm and not greater than 500 nm and growth of the InP crystal or a compound semiconductor crystal whose lattice constant is closer to that of InP than that of GaAs is conducted at a temperature of not lower than 400° C. and not higher than 700° C.

10. The method of producing a compound semiconductor as claimed in claim 8, wherein an InP buffer layer is grown on the InGaP buffer layer or InGaAsP buffer layer, the InP buffer layer is raised in temperature to a prescribed annealing temperature and annealed, and the temperature is lowered to a prescribed crystal growth temperature for growing the InP crystal or compound semiconductor crystal whose lattice constant is closer to that of InP than that of GaAs, whereafter the InP crystal or compound semiconductor crystal is grown.

11. The method of producing a compound semiconductor as claimed in claim 10, wherein growth of the InGaP buffer layer or InGaAsP buffer layer is conducted at a temperature of not lower than 400° C. and not higher than 600° C. to a thickness of not less than 5 nm and not greater than 300 nm.

12. The method of producing a compound semiconductor as claimed in claim 10 or 11, characterized in that the thickness of the InP buffer layer is not less than 20 nm and not greater than 200 nm.

13. The method of producing a compound semiconductor as claimed in claim 10, characterized in that the growth temperature of the InP buffer layer is not lower than 400° C. and not higher than 550° C.

14. The method of producing a compound semiconductor as claimed in claim 10, wherein the InP buffer layer is raised in temperature to a prescribed annealing temperature and annealed, and then, before growing the InP crystal or compound semiconductor crystal whose lattice constant is closer to that of InP than that of GaAs, an operation for lowering the temperature from the prescribed annealing temperature to a prescribed crystal growth temperature and again raising it to the prescribed annealing temperature is repeated not less than one time and not more than five times, whereafter the temperature is lowered to the prescribed crystal growth temperature.

15. The method of producing a compound semiconductor as claimed in claim 10, wherein the prescribed annealing temperature is not lower than 650° C. and not higher than 730° C.

16. The method of producing a compound semiconductor as claimed in claim 10, wherein the prescribed crystal growth temperature is not lower than 400° C. and not higher than 700° C.

17. The method producing of a compound semiconductor as claimed in claim 8, wherein the compound semiconductor crystal whose lattice constant is closer to that of GaAs is InGaAs or InAlAs crystal.
